(19) United States
(12) Patent Application Publication
(10) Pub. No.: US 2026/0127328 A1
(43) Pub. Date: May 7, 2026

(54) METHOD AND SYSTEM FOR CAPTURING AND MANAGING CHANGES TO A HISTORY-BASED PART MODEL

(71) Applicant: Siemens Industry Software Inc., Plano, TX (US)

(72) Inventors: Douglas King, Cambridge (GB); Howard Mattson, Cambridge (GB); Dick Baardse, Geldermalsen (NL); Jeremy Rogers, Cambridge (GB); Gang Hu, Chendu (CN); Nicholas Ozanne, Cambridge (GB); Michael Copley-May, Cambridge (GB); Feng Yu, Irvine, CA (US); Kai He, Sichuan (CN)

(21) Appl. No.: 19/119,914

(22) PCT Filed: Oct. 26, 2022
(86) PCT No.: PCT/US2022/047808

§ 371 Date: Apr. 10, 2025

(51) Int. Cl. G06F 30/17; G06F 30/12

(52) U.S. Cl. CPC G06F 30/17; G06F 30/12

(57) ABSTRACT

A computer-implemented method and a system for capturing and managing changes to a history-based part model are described. The changes are generated external to the part and are stored as a feature within the history-based modelling system. The method and system are used in the context of a part assembly edit. A user supplies a generic change to the part assembly in the form of an initial driving change. This is analyzed to determine consequential changes within the model that need to be made to preserve the consistency of the model of the part assembly. For each part affected by the generic change, part-level shape-changes generated external to the part are captured in a new shape-change feature and stored at the end of the current feature history of the part

[symbol]

### TECHNICAL FIELD

The present disclosure relates to a computer-implemented method of and system for capturing and managing changes to a history-based part model, wherein the changes are generated external to the part, wherein each change to the shape of a part in the part model is stored as a feature within the history-based modelling system, and wherein part-level changes to the model are separated from the assembly-level changes to the model, the method being used in the context of a part assembly edit.

### BACKGROUND

Computer-Aided Design (CAD) has offered, for many years, the ability to edit the shape of a part directly and then solve dependent assembly constraints, thus enabling all the positions of the part to adapt accordingly. With the advent of Synchronous Technology, shape-change in multiple parts can happen simultaneously with assembly part position change. In a history-free modelling system such changes can simply be applied straight into the CAD model, but this is not the case in history-based modelling systems. In a history-based modelling system, each shape-change to each part must be captured as a feature, with the features then being arranged in order to form a recipe for creating the part. The recipe (or history) can be replayed at any point during the design process, thus enabling a user to go back and edit individual features or to change the order of individual features to affect the final model produced. To ensure that a complete history of the shape-changes is maintained new edits are captured and managed as shape-change features in the history of the part model. Each part in the model will therefore have a feature history, with any new features added into the feature history that is current for the part at the time the change is made. This is illustrated using a simple example as shown in FIGS. 1a and 1b.

FIG. 1a is a schematic diagram of a first synchronous assembly edit. A part 10 includes four interlinked parts 11, 12, 13, 14, 15, where the first part 11 is in contact with the second part 12, the second part 12 is connected to the third part 13 by a pivot, and the third part 13 is connected to the fourth part 14 also by a pivot. An edit is applied where the second part 12 is moved downwards, as illustrated by arrow A, which not only moves the first 11, third 13 and fourth 14 parts, as illustrated by arrow B, but changes the shape of the first part 11. The part 15 remains unchanged. This is done by applying a linear transform to one of the faces of the first part 11. If the first part 11 is a history-based part, then this shape-change must be captured as a shape-change feature to maintain the part integrity. FIG. 1b is a schematic diagram of a second synchronous assembly edit. A part 16 includes five interlinked parts 17, 18, 19, 20, 21, arranged in a substantially rectangular shape, with the first, 17, second 18, third 19, and fourth 20 parts framing the fifth 21. Each part of the first, 17, second 18, third 19, and fourth 20 parts is pivotably connected to two of the other parts. The first 17, second 18, and fourth 20 parts each link to a hole 22, 23, 24 in the fifth part 21. On moving the first 17 part to the right to a new position, each part of the second, 18, third 19, and fourth 20 parts move relative to this new position due to their pivotable connections. However, this also drives the holes 22, 23, 24 within the fifth part 21 to move in either the x, y, or z direction. If the fifth part is a history-based part, these three shape-changes must be captured to maintain the part's integrity.

Part assembly edits are merely one example of potential shape-changes on a part, which can be characterized by the following features: changes computed by a process outside of the part but needing to be captured within the part; changes that are low-level geometry changes rather than edits that a user would understand naturally.

Such shape-changes can also be generated in other contexts, such as part of a model optimization process or part of a topology optimization process. For example, during engineering analysis, it may be necessary to change the shape of a model to increase strength or to minimize the use of construction materials. This creates a more generic issue than merely those encountered in the editing examples of FIGS. 1a and 1b above.

An additional complication is that in many potential applications the resulting shape-changes within a part are not always simple, and hence not always immediately obvious or understandable to the user (such as with low-level geometry changes). Edits may involve multiple related entities within a part, with each entity changing in different and complex ways. For example, moving a face in a linear direction may move adjacent tangent faces with a completely different motion, and involve several identified dependent blends or chamfers that must also be updated for the edit to be successful. All of this information must therefore be captured within the relevant shape-change feature. For a low-level system that is tasked with supporting generic shape-changes, the generation and editing of such shape-change features may present a number of issues such as: the generation, capture and application of low-level generic shape-changes to a model to support the creation of a feature; the re-application of low-level generic shape-changes to support feature replay; and the edit of low-level generic shape-changes to support feature edit.

There exists, therefore, for a number of modelling scenarios in history-based modelling systems, a need for techniques to deal with the interaction between the history-based nature of a part and assembly edits or optimizations, such as model and topology.

### SUMMARY AND DESCRIPTION

The embodiments of the present disclosure aim to address these issues by providing, in a first aspect, a computer-implemented method of capturing and managing changes to a history-based part model, wherein the changes are generated external to the part, wherein each change to the shape of a part in the part model is stored as a feature within the history-based modelling system, and wherein part-level changes to the model are separated from the assembly-level changes to the model, the method when used in the context of a part assembly edit including: a) receiving, from a user, a generic change to the part assembly in the form of an initial driving change; b) analyzing the initial driving change in the context of the model of the part assembly to determine consequential changes within the model that need to be made to preserve the consistency of the model of the part assembly; for each part affected by the generic change: c) capturing part-level shape-changes generated external to the part in a new shape-change feature, the new shape-change feature being associative and stored at the end of the current feature history of the part; and d) updating the model of the part assembly and displaying to the user.

Capturing part-level changes based on generic changes made outside of the part itself, even in complex systems, and storing this as an associative shape-change feature in the feature history of the part provides the user with the ability to apply generic changes and engage in robust feature re-playing.

For each part affected by the generic change, the method may further include capturing the changes in a new shape-change package stored as a shape-change feature in the part history of the modelling system.

At a part level, each feature may include a plurality of editable parameters in the form of local driving changes, and wherein each local driving change is formed by:
i) determining the local driving entities within the part based upon the relationships between entities within the part, and ii) determining the changes each local driving entity undergoes in the change to the part assembly.

The determining of the local driving entities may include: A) converting each part within the assembly that is affected by the generic change into a graph representation, wherein each entity is a node in the graph; B) grouping together, within the same part, the nodes that will change shape as shape-change nodes; C) grouping together shape-change nodes that are connected within the graph to form independent groups; and, for each independent group within a part: D) determining the distance between each shape-change node in a group and the part in the assembly undergoing the initial driving change; and E) choosing the shape-change node in each group with the shortest distance to the part in the assembly undergoing the initial driving change as the local driving entity for that group.

The determining of the changes each local driving entity undergoes in the change to the part assembly may include: A) determining the type of change each local driving entity will undergo in the changes to the part assembly; and B) storing the changes each local driving entity undergoes in the shape-change package.

The method may further include: generating editable parameters in the feature history-based on the local driving entity and the change the local driving entity undergoes; and providing access to the editable parameters to enable the user to edit the feature in a subsequent editing process.

The declaration of a change may be received from the user in the form of a part selection and a part movement.

The method may further include: replaying the feature history of the part without reference to the declaration of a change from the user; enabling editing features from the current feature history that occurred prior to and post the generation of the new shape-change feature; and enabling editing of the new shape-change feature subsequent to its creation in order to modify its parameters.

The method may further include storing additional features within the feature history post the new shape-change feature and allowing further changes to the part.

An entity may be a vertex, edge, face, or geometry.

A parameter may be a move in direction, a rotation, a move in plane, a change in radius, a change in minor radius, or a change in half-angle.

In a second aspect, the present disclosure also provides a computer program product containing instructions, which, when executed on a computer, cause the computer to perform the steps outlined above.

In a third aspect, the present disclosure also provides a data processing system configured to capture and manage changes to a history-based part model, wherein the changes are generated external to the part, wherein each change to the shape of a part in the part model is stored as a feature in the history of the part model within the modelling system, and wherein part-level changes to the model are separated from the assembly-level changes to the model, including: a user input device configured to receive a generic change to the part assembly in the form of an initial driving change; a processor configured to analyze the initial driving change in the context of the model of the part assembly to determine consequential changes within the model that need to be made to preserve the consistency of the model of the part assembly, and for each part affected by the generic change capture part-level shape-changes generated external to the part in a new shape-change feature, the new shape-change feature being associative, and to update the model; a memory associated with the processor and configured to store the new shape-change feature at the end of the current feature history of the part; and a display device configured to display the updated model to the user.

### BRIEF DESCRIPTION OF THE DRAWINGS

The present disclosure is now described by way of example only, and with reference to the accompanying drawings, in which:

FIG. 1a is a schematic diagram of a first synchronous assembly edit;

FIG. 1b is a schematic diagram of a second synchronous assembly edit;

FIGS. 2a, 2b, and 2c are a schematic illustration of a generic change in an assembly edit in accordance with embodiments of the present disclosure;

FIG. 3 is a flowchart illustrating an embodiment of the method;

FIG. 4a is a schematic representation of a first assembly edit of a part assembly within a CAD model in accordance with an embodiment;

FIG. 4b illustrates the local driving entities of the assembly edit in FIG. 4a as a graph;

FIGS. 5a to 5d show the stages of determining local driving entities in the example illustrated in FIGS. 4a and 4b;

FIGS. 6a to 6d show the stages of determining local driving entities in a second example according to an embodiment;

FIGS. 7a to 7d show the stages of determining local driving entities in a third example according to an embodiment;

FIG. 8 is a series of illustrations of the effects of editing a shape-change feature in accordance with embodiments; and

FIG. 9 illustrates an example of a data processing system in which an embodiment of the present disclosure may be implemented.

### DETAILED DESCRIPTION

Embodiments of the present disclosure provide a solution to the issues outlined above within a computer-implemented method of capturing and managing changes to a history-based part model, wherein the changes are generated external to the part. External changes are those that are created in relation to a part within an assembly, and which have a consequential effect on a history-based part. Within a history-based model, each change to the shape of a part in the part model is stored as a feature within the history of that part, and part-level changes to the model are separated from the assembly-level changes to the model. The method, when used in the context of a part assembly edit includes receiving, from a user, a generic change to the part assembly in the form of an initial driving change. Next, this initial driving change is analyzed in the context of the model of the part assembly to determine consequential changes within the model that need to be made to preserve the consistency of the model of the part assembly. This also acts to preserve the integrity of the parts within the model. For each part affected by the generic part-level shape-changes generated external to the part are captured in a new shape-change feature, with the new shape-change feature being associative and stored at the end of the current feature history of the part. The model of the part assembly can then be updated and displayed to the user.

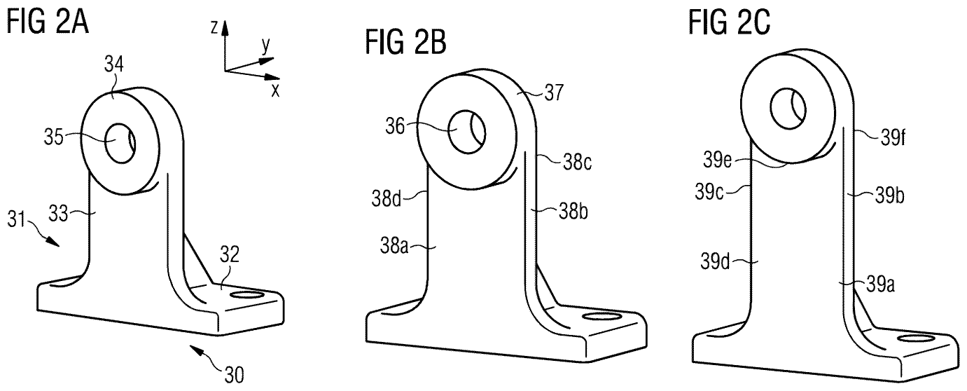

FIGS. 2a, 2b, and 2c are a schematic illustration of a generic change in an assembly edit in accordance with embodiments of the present disclosure. FIG. 2a is a schematic illustration of a single part 30 having a substantially “L”-shaped main body 31 formed from a base portion 32 in the x, y-plane, and perpendicular upright 33 in the z-plane. At the end of the perpendicular upright 33 distal from the base portion 32, a circular head 34 is positioned, having a central through-hole 35 such that the head 34 forms a ring shape due to the concentric nature of the through hole 35 and the circular head 34. The through-hole 35 is delineated by an inner face 36 that effectively forms the inner boundary of a hollow cylinder. This is concentric with an outer face 37 that forms the external boundary of the head 34. The perpendicular upright 33 has four planar faces 38a, b, c, d arranged at right angles to one another: two large opposing planar faces 38a, b and two small opposing planar faces 38c, d. Blend faces 39a-f occur where the planar faces 38a-d of the perpendicular upright 33 meet, and where the outer surface 27 of the head 34 meets the large opposing faces 38a, b of the perpendicular upright 33.

Initially, a user indicates (by moving a cursor, for example) that the generic change they wish to make is to move the face 36 forming the boundary of the through-hole 25 in the head 34 upwards in the z-direction, away from the base portion 32. This movement forms the initial driving change, and as shown in FIG. 2b, the CAD system analyses the model of the part 30 and determines that the following must be updated to maintain the integrity of the part: the cylindrical face 37; the planar faces 38a, b, c, d of the perpendicular upright 33; and the blend faces 39a, b, c, d, e, f.

The cylindrical face 37 forming the boundary of the head 34 needs to move upwards in the z-direction, and the planar faces 38a, b, c, d, and their associated blend faces 39a, b, c, d need to be extended. These additional changes are required for the CAD system to determine that the initial diving change can be made.

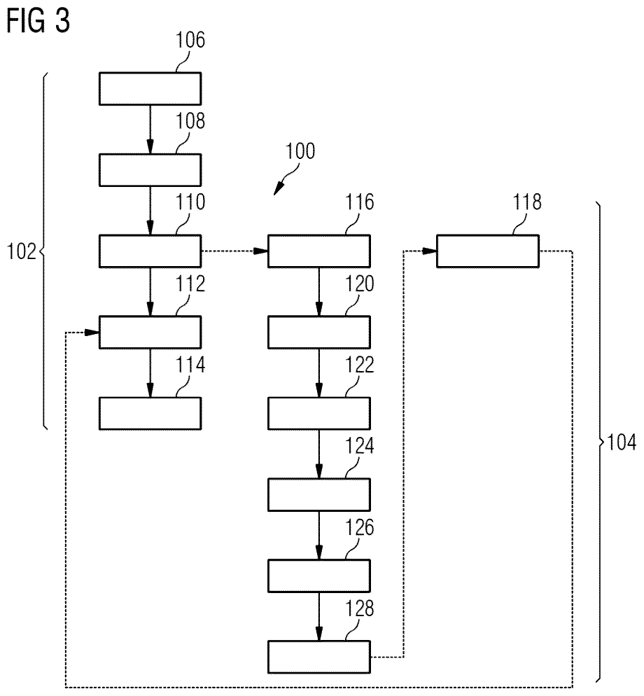

FIG. 2c illustrates the part 30 as the initial driving change is made by the user. As this happens, the model is updated by translating the face 36 forming the boundary of the through-hole 35 and the cylindrical face forming the boundary of the head 34, extending the planar faces 38a, b, c, d of the perpendicular upright 33 and re-blending the blend faces 39a, b, c, d between the planar faces 38a, b, c, d of the perpendicular upright 33. These generated low-level changes describe a repeatable edit to the model that can be captured as a feature in the part. The shape-change feature will then be included in the current feature history of the part. This is described in more detail with respect to FIG. 3.

FIG. 3 is a flowchart illustrating an embodiment of the method. The method 100 is applied to capture and manage changes to a history-based part model and can be split into two parts: a method 102 for generating, capturing, and applying generic shape-changes on a part for storage as a feature; and a method 104 for analyzing the generic shape-changes for presentation to a user for edit. Although in the following examples generic changes within the context of an assembly edit are considered, any context in which a shape-changes within a history-based model is suitable for the embodiments to be applied within. In addition, within a history-based modelling system the part level changes are separated from the assembly level changes.

The method 102 begins at step 106 where a generic change to a part assembly is received in the form of an initial driving change. This is a declaration of the change that the user wishes to make, and, for example, includes moving the face of a part or editing a dimension of a part. Next, at step 108, the initial driving change is analyzed in the context of the model of the part assembly to determine any consequential changes within the model that need to be made to preserve the consistency of the model of the part assembly. This analysis will also maintain any intuitive behavior for the user that is associated with the part model. This may involve, for example, checking for dimensions, geometric relationships, features and general behavior preferences within the remainder of the part model that could be impacted by the initial driving change. At this point, for each part affected by the generic change made by the user, at step 110, part-level shape-changes that are generated external to the part (in other words, those where the part is affected by changes to another aspect of the part assembly) are captured in the form of a new shape-change feature. Each part has its own feature history, which indicates the order in which edits have been applied to the part within the history-based model. The current feature history of the part will begin with the first edit made and end with the most recent, previous edit, and hence storing the shape-change feature generated in response to the initial driving change received from the user at the end of this current feature history is the most logical implementation of the shape-change feature technique. The captured low-level changes are different for each model and each edit. Each change will consist of the entities involved, the type of change to be made and the specific data relating to that change. Examples of entities, change types and additional data are illustrated in Table 1 below:

TABLE 1
Entity, change type and additional data relating
to generic changes received from a user

| Entities Involved | Change Type | Additional Data |
|---|---|---|
| Vertices, edges, | Translation | Direction, distance |
| faces, geometry | | |
| Vertices, edges, | Rotation | Axis, angle |
| faces, geometry | | |
| Vertices, edges, | Scale | Position, value |
| faces, geometry | | |
| Edges, faces | Blend | Radius |
| Edges, faces | Chamfer | Offsets |
| Edges, faces | Replace | New geometry |
| | | definition |
| Edges, faces | Patch | Collection of faces |
| Faces | Recreate/edit hole | Hole description |
| Edges, faces | Cut/copy/paste | — |
| Edges, faces | Remove/recreate feature | Feature description |

All of the shape-changes are stored as a shape-change package at step 112. This shape-change package is stored in the high-level modelling system as part of a shape-change feature and presented to the user in the history of the part. Once the shape-changes are captured and stored, they are applied using existing modelling local operations technology, which at step 114, results in updating the model of the part assembly and displaying this to the user.

Turning to the second part 104 of the method 100, it is necessary to determine the local driving changes for each part as a part of the initial driving change and store these as additional data in the shape-change package within the part history. At a part level, each feature includes a plurality of editable parameters in the form of local driving changes. The determination of each local driving change is done in two stages, starting at step 116, where the local driving entities within the part are determined based upon the relationships between entities within the part. An entity, as illustrated in Table 1 above, is a vertex, edge, face, or geometry of a part. The relationships between entities will partly determine the external changes a part is subject to following the receipt of an initial driving change from a user. The second stage therefore is to determine, at step 118, the changes each local driving entity undergoes in the generic change to the part assembly.

The local driving entities themselves are determined using a series of substeps based upon nodes in a graph representation. At step 120, each part within the assembly that is affected by the generic change is converted to a graph representation, where each entity (such as a vertex, edge, face, or geometry) is a node in the graph and the relationships between entities, both within a part and between parts, are edges in the graph. At step 122, nodes that will change shape within the same part are grouped together as shape-change nodes. Then, at step 124, all the shape-change nodes within a single part that are connected are grouped together to form independent groups. For each independent group within the graph that falls within the same part, at step 126, the distance between each shape-change node in the group and the part in the assembly undergoing the initial driving change is determined. At step 128, the shape-change node in each group with the shortest distance to the part in the assembly that undergoes the initial driving change is chosen as the local driving entity for that group.

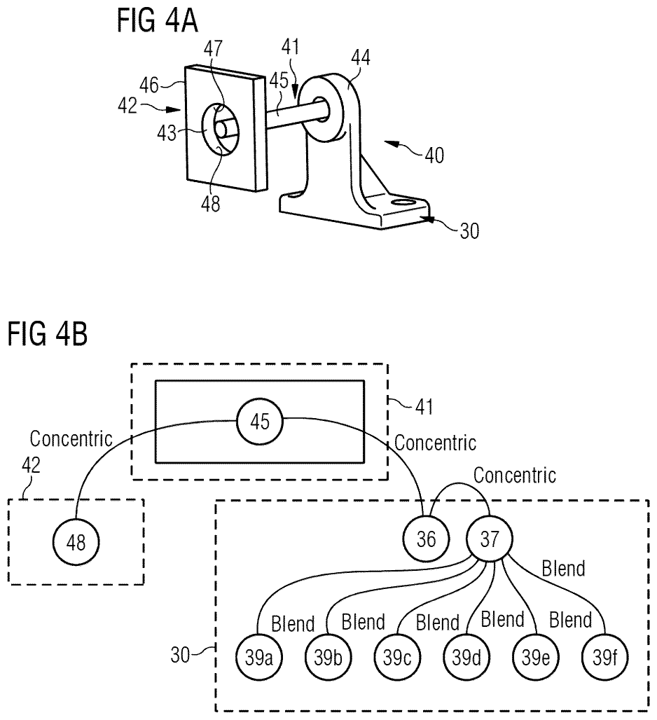

This process is shown in more detail in FIGS. 4a and 4b. FIG. 4a is a schematic representation of a first assembly edit of a part assembly within a CAD model in accordance with an embodiment. The part assembly 40 includes the part 30 first illustrated in FIGS. 2a, b, and c above, but in this example, arranged with a second 41 and third 42 part. The second part 41 is a closed cylinder including two opposing end faces 43, 44 joined by a long face 45 forming a continuous surface between them. The second part 41 is positioned within the through-hole 35 of the head 34 of the first part 30 and has a smaller diameter than that of the through-hole 35 to enable this. The third part 42 includes a cuboid body 46 with a central circular through-hole 47 having an inner surface 48 in which the second part 41 is positioned. The diameter of the through-hole 47 is much greater than that of the closed cylinder of the second part 41. If a user indicates that they wish to make a generic change by moving the second part 41 upwards in the z-direction, away from the base portion 32 of the first part 30, then, in addition to the changes that were required to move the face 36 of the through-hole 35 in FIG. 2a, it will also be necessary to make changes to the through-hole 47 of the third part 42. As a consequence, the inner surface 48 of the through-hole 47 will also need to move upwards in the z-direction for the local driving changes to be possible.

All of these changes must happen to the model simultaneously and consistently to maintain the integrity of the model and for the edit to make sense. Therefore, offering the user the ability to make these edits individually is not helpful, since this may cause some of that consistency to be lost. The ability to edit the local driving changes themselves however, as part of a playback function, is useful, and this may be based on the faces in FIG. 4a that must move together during the edit. The most obvious face to enable this with would be the face 36 forming the boundary of the through-hole 35 in the head 34 of the first part 30. This face is connected directly to the second part 41 by assembly constraints. But to do this requires the ability to determine the local driving entities, as outlined in general above.

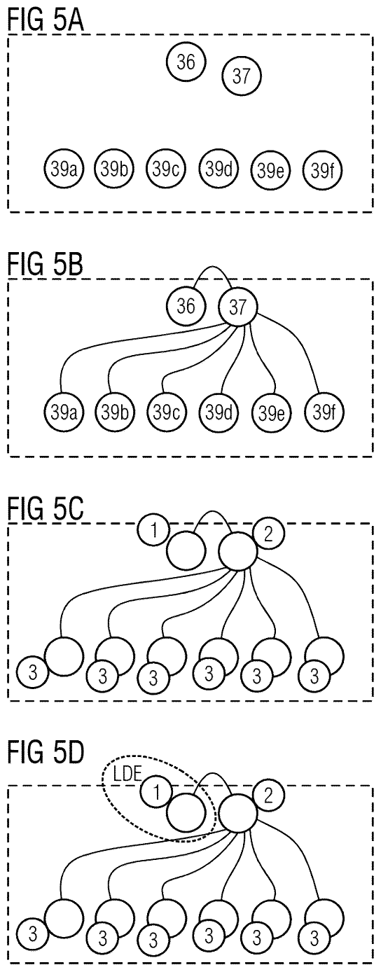

Determining the local driving entities requires the analysis of the relationship between the entities in the system. Each entity can be represented as a node in a graph, connected by edges representing the various connections formed by constraints, dimensions, features and other model parameters. FIG. 4b illustrates the local driving entities of the assembly edit in FIG. 4a as a graph. Like face references are given to like nodes in the graph for clarity. The graph includes three elements: nodes relating to the second part 41 (as this is indicated as being that the user wishes to move); nodes relating to the third part 42 and nodes relating to the first part 30. At the top of the graph, the second part 41 is represented as a rigid collection of the three faces of the cylinder—the two end faces 43, 44 and the connecting face 45 along the length of the cylinder—because it is a non-shape changing part in the assembly, only its position can change. The collection of faces is represented as a rigid collection of nodes as there are no changes to the faces 43, 44, 45 of the second part 41 during the generic change, illustrated as a solid box around the nodes. The cylindrical face 45 is linked to the inner surface 48 of the through hole 47 in the third part 42 by a concentric relationship. Only one face of the third part 42 is at issue in terms of deriving the initial driving changes. The cylindrical face 45 of the second part 41 is also linked to the inner surface 36 of the through hole 35 in the head 34 of the first part 30, again by a concentric relationship. This inner surface 36 shares a concentric relationship with the face 37 forming the boundary of the head 34. The face 37 forming the boundary of the head 34 is linked to each of the blend surfaces 39a, b, c, d, e, f by a dependent blend. Following the method outlined above, the local driving entity based in the graph can be determined. This is illustrated in further detail in FIGS. 5a to 5d, which show the stages of determining local driving entities in the example illustrated in FIGS. 4a and 4b.

As shown in FIG. 4b, the first part 30 includes a number of faces that may be affected by a change in the position of the second part 41. FIG. 5a illustrates the graph representing the grouping of shape-change nodes in the first part 30 shown in FIG. 4a. This contains all of the nodes representing the faces impacted by the movement of the second part 41: the inner surface 36 of the through-hole 35 in the head 34 of the first part; the surface 37 forming the boundary of the head 34; and the blend faces 39a, b, c, d, e, f that connect the head 34 to the perpendicular upright 33 of the first part. The faces 38a, b, c, d of the perpendicular upright 33 are not shown as nodes as these will be extended as a result of the dependent blend relationship between the face 37 forming the boundary of the head 34 and the blend faces 39a, b, c, d, e, f. FIG. 5b illustrates the graph for the first part 30 after connected shape-change nodes in the same part are grouped. In this example, there is no effect on the grouping of shape-change nodes in the first part 30 but, depending upon the part in question, it may be necessary to update the graph to better reflect the relationship between shape-change nodes. In FIG. 5c, the graph is annotated to indicate the distance of each shape-change node from the original operation—the movement of the second part 41. The inner face 36 of the through-hole 35 in the head 34 of the first part 30 is marked as “1”, the face 37 forming the boundary of the head 34 is marked as “2”, and the blend faces 38a, b, c, d, e, f are marked as “3”. As illustrated in FIG. 5d, the shape-change node that is closest to the operation is chosen as the local driving entity LDE. In this example, this is the inner surface 36 of the through-hole 35 in the head 34 of the first part 30. Once the local driving entity has been determined, the local driving entity can be stored along with the local driving changes that are applied to it as part of the shape-change package, which in turn will be stored as an associative shape-change feature in the current feature history of the first part 30.

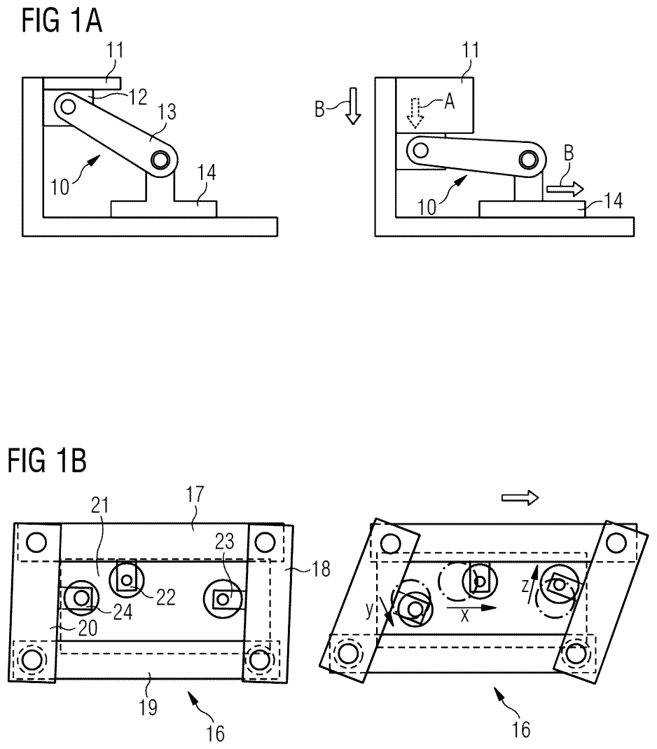

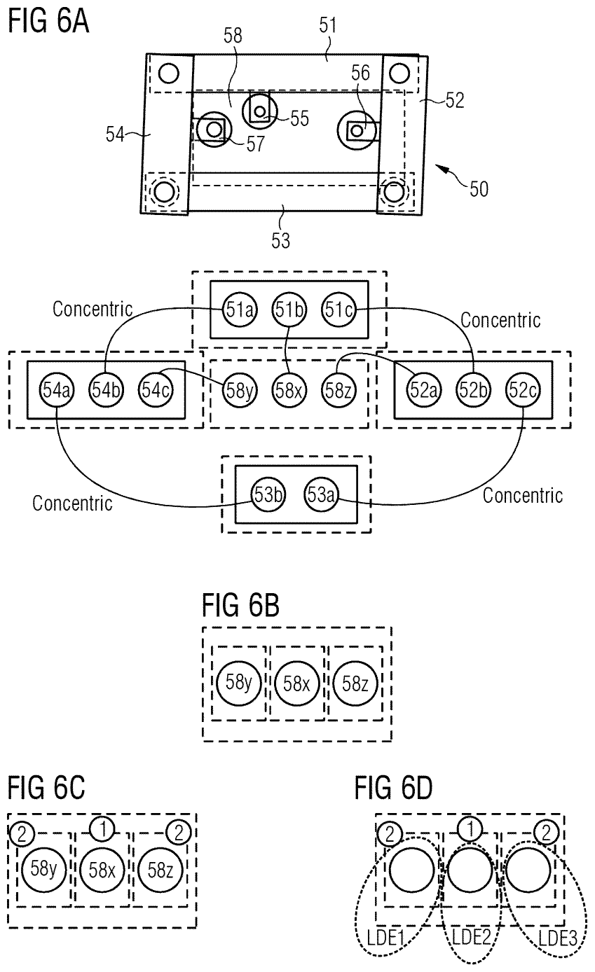

FIGS. 6a to 6d show the stages of determining local driving entities in a second example according to an embodiment. This second example is based on the complex part shown in FIG. 1b. A part 50 includes four interlinked parts 51, 52, 53, 54, where the first part 51 is in contact with the second part 52, the second part 52 is connected to the third part 53 by a pivot and the third part 53 is connected to the fourth part 54 also by a pivot. The first 51, second 52, and fourth 54 parts each link to a hole 55, 56, 57 in a fifth part 58, positioned centrally between the other four interlinked parts 51, 52, 53, 54. A user indicates that they wish to make a generic change by moving the first interlinked part 51 from left to right, causing a graph to be generated. Again, like face references are used to indicate like nodes within the graph. Starting at the center of the graph, with the fifth part 58, the three faces 58x, 58y, 58z that form the inside of the three holes 55, 56, 57, respectively, are grouped as shape-change nodes in the fifth part 58. It should be noted that these shape-change nodes are not rigidly grouped. Next, the same is done for the faces of each of the other four interlinked parts 51, 52, 53, 54 that are affected by the assembly edit indicated by the user. Starting with the first part 51, this is represented by three rigidly grouped shape-change nodes representing the three faces 51a, 51b, 51c affected by the assembly edit. Similarly, the second 52 and fourth 54 parts each have three faces a, b, c, which are affected by the assembly edit and rigidly grouped. However, since the third part 53 does not have a connection to the fifth part 58, only two of its faces will be affected by the assembly edit, creating two rigidly grouped shape-change nodes. Again, rigid groupings of nodes that represent faces that are unaffected by the initial driving change are indicated in solid boxes. Finally, the edges indicating the relationships between the shape-change nodes in each part of the graph are added. The three faces 58x, 58y, 58z of the fifth part all have a concentric relationship with the respective face 51b, 52c, 54a of the first 51, second 52, and fourth 54 parts. The first part 51 has one face 51a that is concentrically related to one face 52b in the second part 52, and one face 51c concentrically related to one face 54b in the fourth part 54. One face 53a of the third part 53 is concentrically linked to the remaining face 52a of the second part, and the other face 53b of the third part 53 is concentrically linked to the remaining face 54c of the fourth part.

The fifth part 58 is the only part in the graph not to have a rigid grouping of faces, hence next, as shown in FIG. 6b, the connected shape-change nodes in the fifth part are grouped to give three independent groups. The first group relates to the second face 58y, the second group relates to the first face 58x, and the third group relates to the third face 58z. Then, as illustrated in FIG. 6c, the distances of each group from the original operation are counted. The second group containing the first face 58x is marked as “1” and both the first and third groups are marked as “2”, because these groups are equidistant from the operation. The closest node to the operation for each group is then chosen. However, the graph for the fifth part 58 contains three independent groups of shape-change nodes, meaning that each group has its own local driving entity LDE, as illustrated in FIG. 6d. Once the local driving entity has been determined it can be stored along with the local driving changes that are applied to it as part of the shape-change package, which in turn will be stored as an associative feature in the current feature history of the fifth part 58.

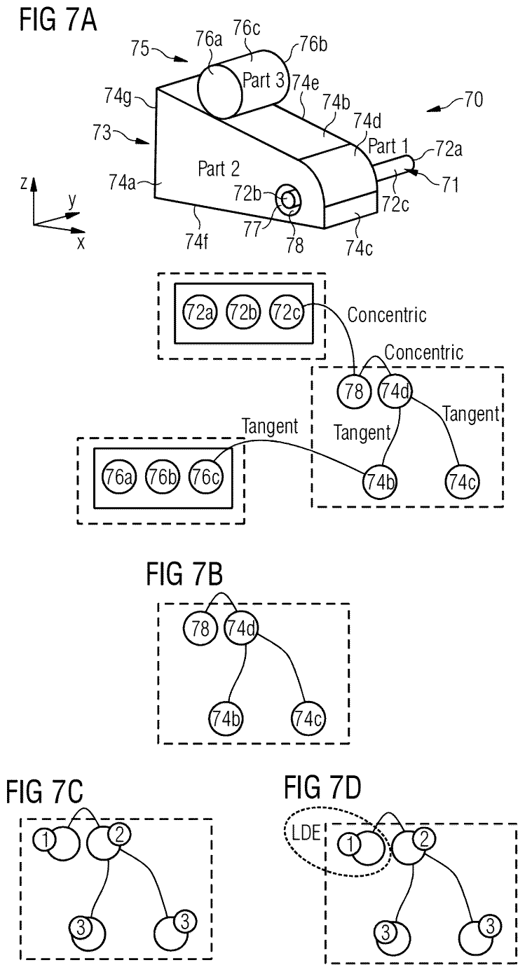

FIGS. 7a to 7d show the stages of determining local driving entities in a third example according to an embodiment. FIG. 7a illustrates a part assembly 70 including three parts: a first part 71 including a solid cylinder having two end faces 72a, b joined by a third face 72c that forms a continuous surface between the first and second end faces 72a, b; a second part 73 including a solid having a front planar face 74a, a top face 74b, a first side face 74c, and a blend face 74d joining the top 74b and first side 74c faces, a rear planar face 74e, a base face 74f, and a vertical second side face 74g; and a third part 75 including a solid cylinder having two end faces 76a, b, joined by a third face 76c. The second part 73 also includes a circular through-hole 77 having an inner surface 78, in which the first part 71 is inserted. The diameter of the through-hole 77 is greater than the diameter of the first part 71 to enable this. The through-hole 77 is also concentric with the blend face 74d. The third part 75 sits on the top face 74b of the second part 73. When a user indicates that they wish to make a generic change by moving the first part 71 upwards or downwards in the z-direction, the graph is generated. Like face references are used to indicate like nodes and rigidly grouped nodes are surrounded by a solid box.

For the first part 71 and the third part 75, the graph includes rigid groupings of the three faces 72a, b, c, 76a, b, c, but for the second part 73 the graph representation is more complex. The inner surface 78 of the through hole 77 has a concentric link to the blend face 74d due to the concentric nature of the blend face 74d and the through hole 77. Both the top face 74b and the first side face 74c have a tangent relationship to the blend face 74d. The graph representation of the second part 73 is linked to those of the first 71 and second 75 parts due to the concentric relationship between the third face 72c of the first part 71 and the inner surface 78 of the through hole 77 and the tangent relationship between the top face 74b of the second part 73 and the third face 76c of the third part 75. Having determined the nodes in the graph for each part to create the graph in FIG. 7a, as the next step, the connected shape-change nodes in the only part not including a rigid group of faces are grouped together, which as illustrated in FIG. 7b, is the second part 73. In FIG. 7c, the distances between the original operation (moving the first part 71) and the individual shape-change nodes are again counted, resulting in the inner surface 78 of the through-hole 77, being marked as “1”, the blend face 74d being marked as “2”, and the top 74b and first side face 74c of the second part being marked “3”. As illustrated in FIG. 7d, the closest shape-change node to the operation for each group is chosen as the local driving entity. Given that the graph representation of the second part 73 has a single grouping, the inner surface 78 of the through-hole 77 becomes the local driving entity. Once the local driving entity has been determined, it can be stored along with the local driving changes that are applied to it as part of the shape-change package, which in turn will be stored as an associative shape-change feature in the current feature history of the second part 73.

In each of the above examples, the techniques of grouping shape-change nodes within a part, grouping connected shape-change nodes and then determining the distance to the original operation are used to determine the local driving entity. In each example, the local driving entity is a face of a part, however, as an entity may be the vertex, edge, face, or geometry of a part, each of these may, depending on the model and assembly edit, be used as a local driving entity as there is no limitation that this must be a face. Once the local driving entities have been determined, the change that each local driving entity undergoes in the original assembly edit is analyzed to determine if it is a movement in a direction, a rotation around an axis, a movement in plane, a change in radius, a change in minor-radius, or a change in half-angle.

For any local driving entities undergoing these edits, and thus affected by local driving changes, the data stored in the shape-change package is given in Table 2:

TABLE 2
Local driving changes stored in the shape-change package

| Parameter Type | Additional Data | Parameter Value | Default Value |
|---|---|---|---|
| Move in direction | Direction vector | Distance from start | Distance in original |
| | | | edit |
| Rotate around axis | Axis definition | Angle from start | Angle in original edit |
| Move in plane | Plane definition | Distances from start | Distances in original |
| | | | edit |
| Change radius | | Radius | Radius in original |
| | | | edit |
| Change minor- | | Minor-radius | Minor-radius in |
| radius | | | original edit |
| Change half-angle | | Half-angle | Half-angle in original |
| | | | edit |

Considering FIGS. 5a-d, 6a-d, and 7a-d, each generic change in an assembly edit results in a new feature being captured for each affected part. In FIG. 5a, the local driving entity resulting from the generic change is the inner surface 36 of the through-hole 35 of the first part 31, and the local driving change is the movement of the second part 41. This results in new features based on the shape-change package being captured for both the third part 42 and the first part 31, because these contain entities that are altered by the initial driving change. In the case of FIG. 6a, there are three local driving entities in the form of the faces 58x, 58y, 58z in the fifth part 58 and the local driving change is the movement of the first part 51. New features based on the shape-change package are captured in relation to the first 51, third 54, fourth 55, and fifth 58 parts. In FIG. 7a, the local driving entity is the inner surface 78 of the through hole 77 of the second part 73, and the local driving change is the movement of the first part 71. A new feature based on the shape-change package is therefore captured in relation to the second part 73 only. This process of breaking down the shape-changes and separating them into features on the individual parts therefore preserves the independence of each component in the assembly. One other advantage is the ability to present data representing local driving entities and local driving changes to a user in an editable format. This then enables the user to replay the assembly edit and make changes to individual aspects of the edit without affecting the entire model. Once a user has made a change to an editable parameter, the shape-change goes through the same process as described above at the assembly level that generated the original shape changes, except that this time the process is performed locally on the part. The initial-driving-change is defined as all of the editable parameters within the shape-change package, either with their initial values or new values that are defined by the user. The initial-driving-change is analyzed in the context of the part model to determine other changes that should be made to the model. This involves, for example, checking for dimensions, geometric relationships, and features. Then the initial-driving-change is made to the part, and the model updates. A further advantage is the ability for a user to access a robust shape-change feature replay. This is discussed in more detail below.

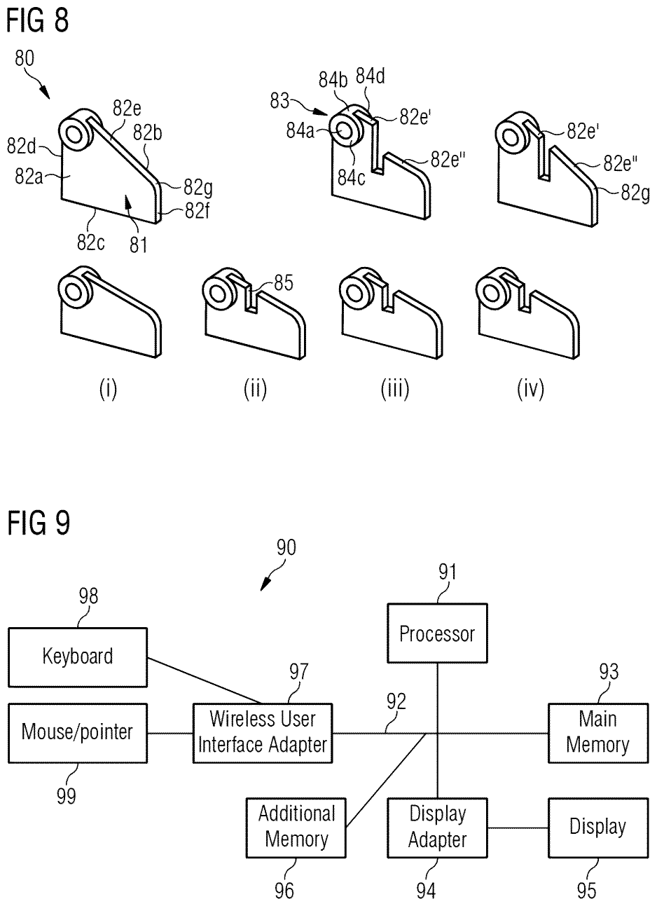

Since editing other features may cause significant structural changes to the part, such as new faces being introduced into the system, in such scenarios, simply applying the original shape-changes is not sufficient to successfully update the shape-change feature. This would result in any additional faces not being taken into account during the subsequent edit. For example, if a hole feature is edited from being a counter-sink hole to a counter-bore hole, this process will introduce new faces. If the original counter-sink hole faces were part of a shape-change feature, moving only the original counter-sink hole faces no longer makes sense, because the new counter-bore hole faces will also need to be identified. Another example of this is illustrated in FIG. 8.

FIG. 8 is a series of illustrations of the effects of editing a shape-change feature in accordance with embodiments. As illustrated in FIG. 8 (i), a part 80 includes a thin body 81 having opposing planar faces 82a, b joined together by five side faces (a base 82c, a long vertical side face 82d, an inclined upper face 82e, a short vertical side face 82f opposite the long vertical side face 82d and a blend face 82g positioned between the inclined upper face 82e and the short vertical side face 82f). A hollow cylinder 83 having concentric inner 84a and outer 84b surfaces and opposing faces 84c, 84d joining the inner 84a and outer 84b faces is positioned on the junction between the longer vertical face 82d and the inclined upper face 82e of the thin body 81, and oriented with an axis A that is concentric with the concentric inner 84a and outer 84b surfaces perpendicular to the opposing planar faces 82a, 82b of the thin body 81. A shape-change feature relating to lengthening the long vertical face 82b of the thin body 81 has already been generated as part of the original edit.

FIG. 8(ii) illustrates the addition of a slot 85 into the inclined upper surface 82e of the thin body 81 after the original generation of the shape-change feature but prior to it in the history of the part. This introduces a new planar face 85 and a new coplanar relationship between the now two halves 82e′, 82e″ of the original inclined upper face 82e. In FIG. 8(iii), the original edit is simply replayed without finding the or maintaining the coplanar relationship between the two halves 82e′, 82e″ of the original inclined upper face 82e and they are therefore now positioned at different inclination angles. This demonstrates undesirable behavior.

However, by making use of local-driving-entities during feature replay, the behavior is improved. This is done by using the same process as when editing the change feature, using local-driving-entities to replay the edit which will include finding the new coplanar face 85 and maintaining the coplanar relationships causes a change in the blend face 82g to maintain the same inclination angle for both halves 82e′, 82e″ of the original inclined upper face 82e. This is illustrated in FIG. 8(iv), where the addition of the slot is now included in a shape-change feature and therefore part of the feature history of the part.

The replaying of the feature history of the part is therefore without reference to the declaration of a change from the user. It is not necessary to know what the original declaration of a change was for the re-playing to take place. The user is able to replay the feature history to a particular point and provide a further generic change (such as the introduction of the slot in FIG. 8(ii)) without needing to re-edit or correct parts or part assemblies once the further generic change is stored in the feature history.

FIG. 9 illustrates an example of a data processing system in which an embodiment of the present disclosure may be implemented, for example a CAD application configured to perform the methods of the embodiments as described herein. The data processing system 90 includes a processor 91 connected to a local system bus 92. The processor 91 is configured to analyze the initial driving change in the context of the model of the part assembly to determine consequential changes within the model that need to be made to preserve the consistency of the model of the part assembly, and for each part affected by the generic change capture part-level shape-changes generated external to the part in a new shape-change feature, the new shape-change feature being associative, and to update the model. The local system bus connects the processor to a main memory 93 and graphics display adaptor 94, which may be connect-ed to a display device 95, with the memory 94 being configured to store the new shape-change feature at the end of the current feature history of the part and the display device being configured to display the updated model to the user. The data processing system may communicate with other systems via a wireless user interface adapter connected to the local system bus 92, or via a wired network, for example, to a local area network. Additional memory 96 may also be connected via the local system bus. A suitable adaptor, such as wireless user interface adapter 97, for other peripheral devices, such as a keyboard 98 and mouse 99, or other pointing device, allows the user to provide input to the data processing system. Other peripheral devices may include one or more I/O controllers such as USB controllers, Bluetooth controllers, and/or dedicated audio controllers (connected to speakers and/or microphones). It should also be appreciated that various peripherals may be connected to the USB controller (via various USB ports) including input devices (e.g., keyboard, mouse, touch screen, trackball, camera, microphone, scanners), output devices (e.g., printers, speakers), or any other type of device that is operative to provide inputs or receive outputs from the data processing system. Further it should be appreciated that many devices referred to as input devices or output devices may both provide inputs and receive outputs of communications with the data processing system. Further it should be appreciated that other peripheral hardware connected to the I/O controllers may include any type of device, machine, or component that is configured to communicate with a data processing system. The user input device, such as the mouse 99, is configured to receive a generic change to the part assembly in the form of an initial driving change. The display device 95 and the input devices (keyboard 98 and mouse 99) are also configured to enable a user to access the re-playing of the feature history and editing of the shape-change features.

An operating system included in the data processing system enables an output from the system to be displayed to the user on the display 95 and the user to interact with the system. Examples of operating systems that may be used in a data processing system may include Microsoft Windows™, Linux™, UNIX™, iOS™, and Android™ operating systems.

In addition, it should be appreciated that data processing system 90 may be implemented as in a networked environment, distributed system environment, virtual ma-chines in a virtual machine architecture, and/or cloud environment. For example, the processor 91 and associated components may correspond to a virtual machine executing in a virtual machine environment of one or more servers. Examples of virtual machine architectures include VMware ESCi, Microsoft Hyper-V, Xen, and KVM.

Those of ordinary skill in the art will appreciate that the hardware depicted for the data processing system 90 may vary for particular implementations. For example, the data processing system 90 in this example may correspond to a computer, workstation, and/or a server. However, it should be appreciated that alternative embodiments of a data processing system may be configured with corresponding or alternative components such as in the form of a mobile phone, tablet, controller board or any other system that is operative to process data and carry out functionality and features described herein associated with the operation of a data processing system, computer, processor, and/or a controller discussed herein. The depicted example is provided for the purpose of explanation only and is not meant to imply architectural limitations with respect to the present disclosure.

The data processing system 90 may be connected to the network (not a part of data processing system 90), which can be any public or private data processing system network or combination of networks, as known to those of skill in the art, including the Internet. The data processing system 90 can communicate over the network with one or more other data processing systems such as a server (also not part of the data processing system 90). However, an alternative data processing system may correspond to a plurality of data processing systems implemented as part of a distributed system in which processors associated with several data processing systems may be in communication by way of one or more network connections and may collectively perform tasks described as being performed by a single data processing system. Thus, it is to be understood that when refer-ring to a data processing system, such a system may be implemented across several data processing systems organized in a distributed system in communication with each other via a network. The data processing system 90 is configured to carry out the methods in accordance with the embodiments described above. For example, the keyboard 98 and mouse 99 may function as a user input device for receiving information from the user, the processor 91 may be configured to carry out the steps of the method and the display 95 configured to display a particular view to the user. A computer product including instructions which, when run on a computer, such as the data processing system 90, may be provided to cause the computer to execute the steps of the methods of the embodiments outlined above.

1. A computer-implemented method of capturing and managing changes to a history-based part model, wherein the changes are generated external to a part, wherein each change to a shape of a part in the model is stored as a feature within a history-based modelling system, and wherein part-level changes to the model are separated from assembly-level changes to the model, the method, when used in a part assembly edit, comprising:
receiving, from a user, a generic change to the part assembly in a form of an initial driving change;
analyzing the initial driving change in a context of the model of the part assembly to determine changes within the model that need to be made to preserve a consistency of the model of the part assembly;
capturing, for each part affected by the generic change, part-level shape-changes generated external to the part in a new shape-change feature, the new shape-change feature being associative and stored at an end of a current feature history of the part;
updating the model of the part assembly; and
displaying the updated model to the user.

2. The computer-implemented method of claim 1, wherein, for each part affected by the generic change, the method further comprises:
capturing the changes in a new shape-change package stored as a shape-change feature in the part history of the history-based modelling system.

3. The computer-implemented method of claim 2, wherein, at a part level, each feature comprises a plurality of editable parameters in a form of local driving changes, and
wherein each local driving change is formed by:
determining local driving entities within the part based upon relationships between entities within the part; and
determining changes each local driving entity undergoes in the change to the part assembly.

4. The computer-implemented method of claim 3, wherein the determining of the local driving entities comprises:
converting each part within the assembly that is affected by the generic change into a graph, wherein each local driving entity is a node in the graph;
grouping together, within a same part, the nodes that change shape as shape-change nodes;
grouping together shape-change nodes that are connected within the graph to form independent groups;
determining, for each independent group within the part, a distance between each shape-change node of the shape-change nodes in a group and the part in the assembly undergoing the initial driving change; and
choosing a shape-change node in each group with a shortest distance to the part in the assembly undergoing the initial driving change as the local driving entity for that group.

5. The computer-implemented method of claim 4, wherein the determining of the changes each local driving entity undergoes in the change to the part assembly comprises:
determining a type of change each local driving entity undergoes in the changes to the part assembly; and
storing the changes each local driving entity undergoes in the shape-change package.

6. The computer-implemented method of claim 4, further comprising:
generating editable parameters in the feature history-based on the local driving entity and the change the local driving entity undergoes; and
providing user to access to the editable parameters to enable the user to edit the feature in a subsequent editing process.

7. The computer-implemented method of claim 1, wherein a declaration of a change is received from the user in a form of a part selection and a part movement.

8. The computer-implemented method of claim 1, further comprising:
replaying the feature history of the part without reference to a declaration of a change from the user,
enabling editing features from the current feature history that occurred prior to and after the generation of the new shape-change feature; and
enabling editing of the new shape-change feature subsequent to creation of the new shape-change feature in order to modify parameters of the new shape-change feature.

9. The computer-implemented method of claim 8, further comprising:
storing additional features within the feature history post the new shape-change feature and allowing further changes to the part.

10. The computer-implemented method of claim 3, wherein an entity of the entities is a vertex, edge, face, or geometry.

11. The computer-implemented method of claim 3, wherein a parameter of the plurality of editable parameters is a move in direction, a rotation, a move in plane, a change in radius, a change in minor radius, or a change in half-angle.

12. A computer program product containing instructions, which, when executed on a computer, cause the computer to
receive, from a user, a generic change to a part assembly in a form of an initial driving change;
analyze the initial driving change in a context of a model of the part assembly to determine changes within the model that need to be made to preserve a consistency of the model of the part assembly;
capture, for each part affected by the generic change, part-level shape-changes generated external to the part in a new shape-change feature, the new shape-change feature being associative and stored at an end of a current feature history of the part;
update the model of the part assembly; and
display the updated model to the user.

13. A data processing system configured to capture and manage changes to a history-based part model, wherein the changes are generated external to a part, wherein each change to a shape of a part in the model is stored as a feature in a history of the model within a modelling system, and wherein part-level changes to the model are separated from assembly-level changes to the model, the data processing system comprising:
a user input device configured to receive a generic change to a part assembly in a form of an initial driving change;
a processor configured to:
analyze the initial driving change in a context of the model of the part assembly to determine changes within the model that need to be made to preserve a consistency of the model of the part assembly;
capture, for each part affected by the generic change, part-level shape-changes generated external to the part in a new shape-change feature, the new shape-change feature being associative; and
update the model;
a memory associated with the processor and configured to store the new shape-change feature at an end of a current feature history of the part; and
a display device configured to display the updated model to a user.
